(19) United States
(12) Patent Application Publication
(10) Pub. No.: US 2023/0156992 A1
(43) Pub. Date: May 18, 2023

(54) COMPONENT PLACEMENT SYSTEMS, MULTI-PIPETTE PLACEMENT HEADS, AND METHODS OF USING THE SAME

(71) Applicant: Kulicke & Soffa Netherlands B.V., Eindhoven (NL)

(72) Inventor: Roy Brewel, Eindhoven (NL)

(21) Appl. No.: 17/985,055

(22) Filed: Nov. 10, 2022

Related U.S. Application Data
(60) Provisional application No. 63/279,522, filed on Nov. 15, 2021.

(51) Int. Cl. H05K 13/04; H05K 13/08

(52) U.S. Cl. CPC H05K 13/041; H05K 13/0411; H05K 13/0409; H05K 13/082

(57) ABSTRACT

A component placement system is provided. The component placement system includes a placement head including a plurality of pipettes. Each of the plurality of pipettes is configured to pick and place components. The component placement system also includes a vacuum source for providing vacuum to each of the plurality of pipettes for holding a component. The component placement system also includes a positive fluid source for selectively providing a positive fluid pressure for releasing the component from a respective one of the plurality of pipettes.

### CROSS-REFERENCE TO RELATED APPLICATION

This application claims the benefit of U.S. Provisional Application No. 63/279,522, filed Nov. 15, 2021, the content of which is incorporated herein by reference.

### FIELD

The invention relates to component placement systems, and more particularly, to improved component placement systems including placement heads having a plurality of pipettes, and methods of using the same.

### BACKGROUND

In the electronics assembly industry, pick and place systems (i.e., component placement systems) are used for the placement of electronic components. In certain placement systems, a plurality of tools (e.g., pick up tools, pipettes, nozzles, etc.) may be carried by a single placement head. Thus, a plurality of electronic components (each carried by a distinct tool) may be carried at the same time by the placement head.

It would be desirable to provide improved component placement systems that overcome one or more of the deficiencies of conventional placement systems including as related to simplicity of design, performance, speed of operation, and equipment cost of ownership.

### SUMMARY

According to an exemplary embodiment of the invention, a component placement system is provided. The component placement system includes a placement head including a plurality of pipettes. Each of the plurality of pipettes is configured to pick and place components. The component placement system also includes a vacuum source for providing vacuum to each of the plurality of pipettes for holding a component. The component placement system also includes a positive fluid source for selectively providing a positive fluid pressure for releasing the component from a respective one of the plurality of pipettes.

Aspects of the invention also relate to methods of using the aforementioned component placement systems, or any component placement system within the scope of the invention.

For example, according to another exemplary embodiment of the invention, a method of operating a component placement system is provided. The method includes the steps of: (a) providing a placement head including a plurality of pipettes; (b) collecting a plurality of components with the plurality of pipettes; and (c) releasing one of the plurality of components from one of the plurality of pipettes by providing a positive fluid pressure to the pipette, while retaining others of the plurality of the pipettes with others of the plurality of pipettes.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1 is a block diagram side view illustrating a component placement system in accordance with an exemplary embodiment of the invention;

FIGS. 2A-2C are perspective views of various placement heads in accordance with various exemplary embodiments of the invention;

FIGS. 3A-3B are block diagram top views illustrating additional component placement systems in accordance with additional exemplary embodiments of the invention;

FIG. 4 is a block diagram illustrating elements of a vacuum control system, a vacuum source, a positive fluid source, and other elements included in a component placement system in accordance with an exemplary embodiment of the invention; and

FIG. 5 is a flow diagram illustrating a method of operating a component placement system in accordance with an exemplary embodiment of the invention.

### DETAILED DESCRIPTION

As used herein, the term “component” refers to any type of electronic component to be placed by a component placement system. Exemplary components include capacitors, resistors, semiconductor die or chips, etc.

According to certain exemplary embodiments of the invention, a component placement system is provided including one or more placement heads, each of the placement heads including multiple individual pipette cartridges (also referred to herein as “control modules”), which are implemented as a functional exchangeable sub module.

Aspects of the invention provide sensitive electronics at the pipette (or placement assembly including the pipette), and enable modularity within a placement head. As used herein, the term “placement assembly” refers to an assembly including a pipette and a respective control module (where the control module includes a controller for controlling motion of the pipette). Thus, aspects of the invention provide exchangeable placement assemblies that include a control module and a pipette. Such placement assemblies (specific to each pipette) may include integrated sensor and drive electronics.

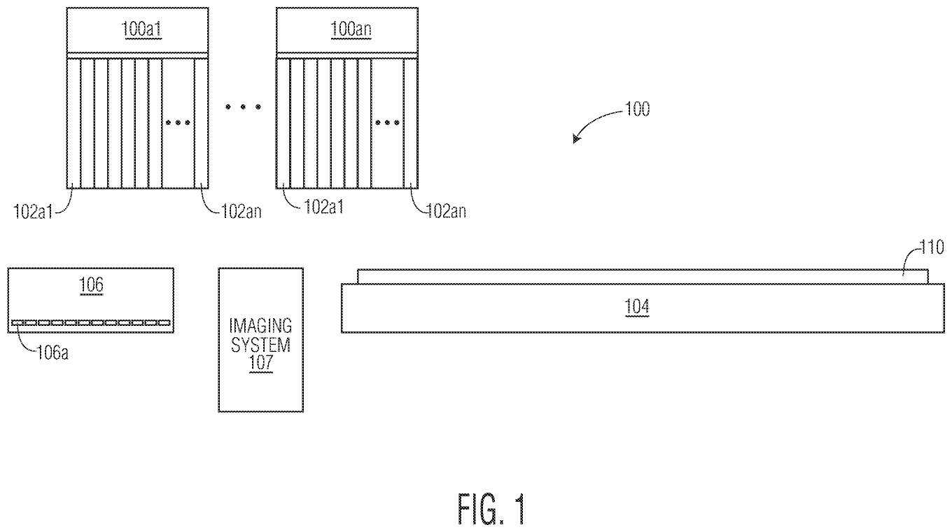

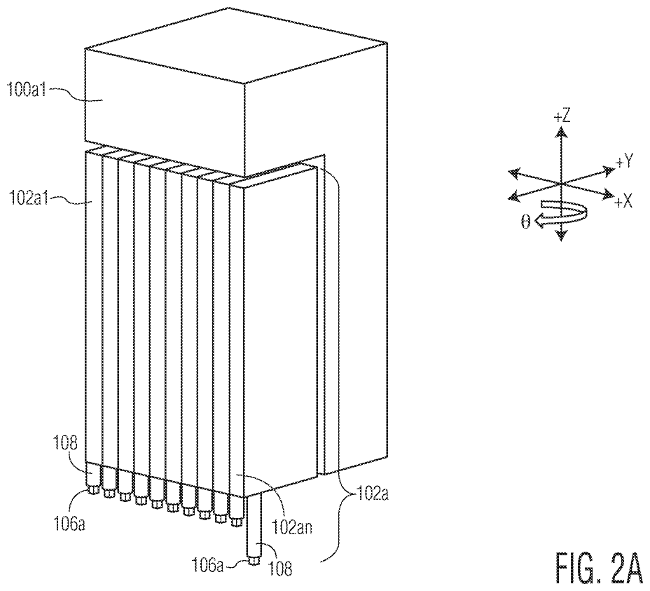

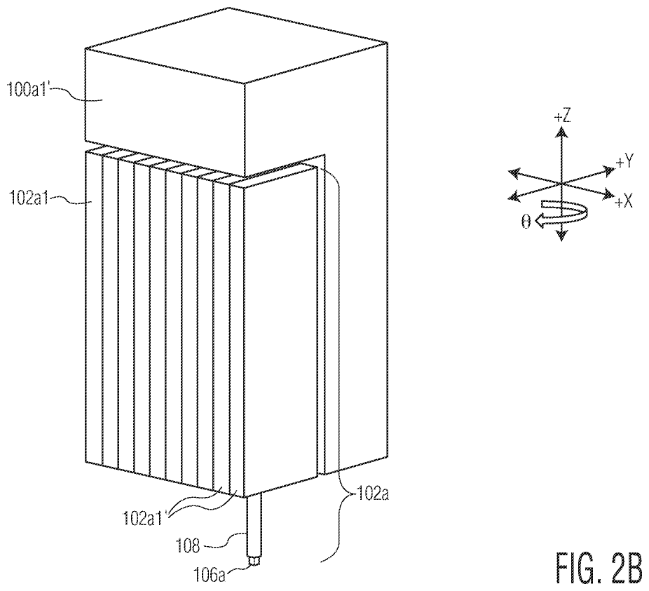

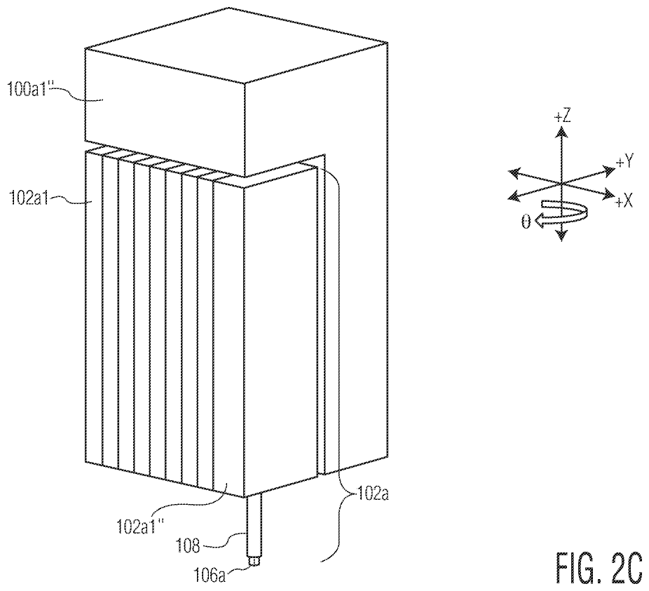

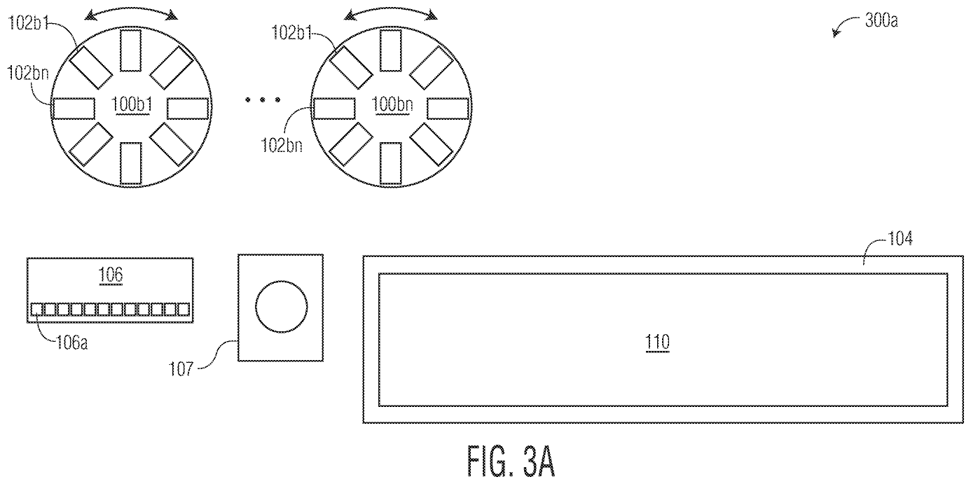

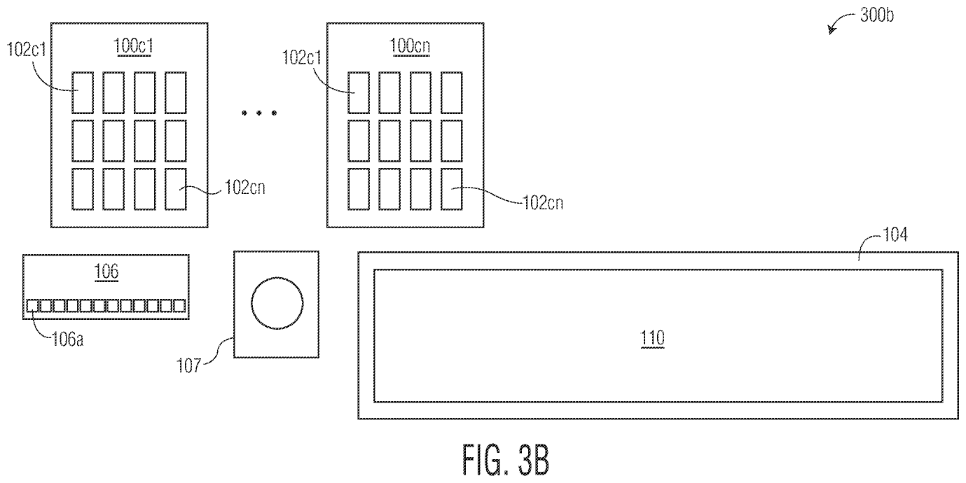

Aspects of the invention relate to placement heads including a plurality of pipettes (and corresponding control modules for each pipette). The pipettes may be arranged in an array configuration (e.g., in a linear array as in FIGS. 1 and 2A-2C, in a matrix array as shown in FIG. 3B, etc.), in an turret configuration (e.g., see FIG. 3A), etc.

In accordance with the invention, each placement head may include (and carry) a plurality of pipettes. For example, a placement head may include: at least 3 pipettes; at least 5 pipettes; at least 10 pipettes; etc.

As will be appreciated by those skilled in the art, a placement head may carry a plurality of components (e.g., one component carried by each of a plurality of pipettes). Typically, a component held by a pipette is rotated and/or generally aligned. Through an inspection process (e.g., using an imaging system including a camera), it may be determined that a component may require further alignment (e.g., using a rotary motor for the given pipette). In accordance with the invention, because each of the pipettes is included in a placement assembly with a respective control module (where the control module controls at least one of z-axis motor current, and theta axis motor current), adjustments may be made in preparation for placing a second component while the placement head is placing a first component. More specifically, while the first component is being placed by a first pipette of the placement head, a relative position of one of more other components held by respective pipettes may be adjusted (e.g., adjusted about a theta axis). In other examples, while a first pipette may be engaged in a pick or place operation (or other motion), z-axis motion of a second pipette (or pipettes) may be commenced. More specifically, in a pick operation, while a first pipette is picking a first component, a second pipette (or pipettes) may begin their descent toward picking another component to save time. Likewise, in a place operation, while a first pipette is placing a first component, a second pipette (or pipettes) may begin their descent toward placing another component (or components) to save time. Of course, such preparation in any of the above examples may be made for multiple components (not just a second component) while picking or placing the first component. This provides for an efficient placement process.

In accordance with aspects of the invention, each pipette may be controlled individually, all of the time. This is important for alignment processes (e.g., using an inspection camera between the component picking process and the component placement process).

According to certain exemplary embodiments of the invention, methods of controlling vacuum (and vacuum breakdown) on a component placement system are provided.

According to certain exemplary embodiments of the invention, a component is released from a pipette while other components are retained (by vacuum) by other pipettes. Typically, the release of the component is in connection with a placement operation. More specifically: a pipette descends to place a component on a workpiece; the component makes contact with the workpiece, as detected by a sensor (e.g., a force sensor integrated with the pipette, or other type of sensor); a positive air pressure is provided to that specific pipette which overcomes vacuum; and then the pipette is raised (which the positive pressure continues) such that the component is released and placed on the workpiece. In another example, the component may be released just before contact, that is, the component “jumps” across a short gap between the pipette and the workpiece. In yet another example, a component may be released separate from a placement operation. For example, a component may be discarded by releasing the component (according to the invention described herein) without placing the component on a workpiece.

Aspects of the invention address the purpose of reducing the number of valves and/or other structures in a vacuum control system of a component placement system. Further aspects of the invention relate to controlling an air pulse to break down the vacuum used to hold a component on a pipette of the component placement system (e.g., an air pulse from a positive fluid source to release the component from the respective pipette) (e.g., an air pulse from a positive fluid source is configured to overcome vacuum provided by a vacuum source at one of the plurality of pipettes to release the component from the pipette). Further aspects of the invention relate to improved detection of the presence (and/or absence) of a component held by a pipette.

According to certain exemplary embodiments of the invention, vacuum breakdown is provided by means of a controllable pressure pulse (e.g., a positive air pressure pulse) without disabling the vacuum supply for individual pipettes. Further aspects of the invention relate to combining flow and pressure sensing to improve detection of the presence (and/or absence) of a component held by a pipette.

According to certain exemplary embodiments of the invention, a vacuum control system which controls the vacuum release of multiple pipettes by overcoming the vacuum level with an injection of pressurized air (or an injection of another fluid/gas) is provided. By using a positive fluid source (such as an injection of pressurized air) to overcome the vacuum used to hold the component by the pipette, the vacuum supply may not be disconnected from the individual pipettes to release the component.

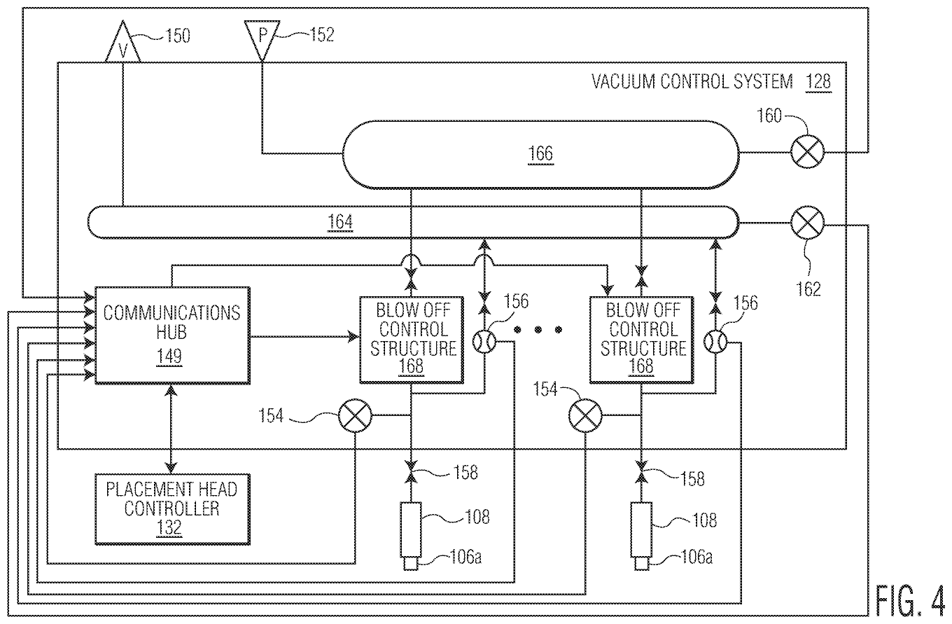

In accordance with aspects of the invention, the vacuum used to hold all of the components with their respective pipettes may comes from an external (or internal) vacuum source that is divided to all pipettes using a vacuum distribution structure (which may also be referred to as a vacuum gallery or vacuum manifold). For example, see vacuum source 150 in FIG. 4, providing a vacuum to central vacuum gallery 164. From central vacuum gallery 164, the vacuum is fed towards the individual pipettes (e.g., through a vacuum restriction).

According to certain exemplary embodiments of the invention, the vacuum flow (and/or the vacuum level) provided is monitored to detect if a component is present or absent at the pipette (e.g., a sensor for detecting whether the component is held by the respective one of the plurality of pipettes). A flow sensor (e.g., see pipette flow sensor 156 in FIG. 4) has a high sensitivity to detect flow through the smallest pipette nozzles in order to detect component absence or presence. The pressure sensor (e.g., see pipette pressure sensor 154 in FIG. 4) detects a vacuum pressure, for example, by detecting where the sensitive flow sensor signal clips (e.g., the pressure sensor can detect a pressure drop when a component is no longer attached, which may be especially useful at component sizes where the flow is too large for a sensitive flow sensor to detect).

When a component needs to be released from a pipette, the blower valve is switched (e.g., see blow off control 168 in FIG. 4) so it releases pressurized air between the pipette and the vacuum restriction. As an alternative, an air buffer may be installed between the blower restriction and the blower valve to decrease the vacuum breakdown time. An pressure regulator can be used to regulate the resulting pressure at the pipette to have a better control of the component release process.

Referring now to the drawings, FIG. 1 illustrates a component placement system 100. Component placement system 100 includes a plurality of placement heads 100a1-100an, etc. Each placement head includes a plurality of control modules 102a1-102an configured for carrying pipettes in an array configuration (e.g., see pipettes 108 in FIG. 2A). Component placement system 100 also includes a component supply 106 including a plurality of components 106a (e.g., where component supply 106 may include a number of component sources, including components of different types, etc.). Component placement system 100 also includes imaging system 107, and support structure 104 for supporting a workpiece 110 (or a plurality of workpieces 110) configured to receive components 106a from pipettes of one or more placement heads 100a1-100an.

Each component placement head 100a1-100an collects components 106a from component supply 106. For example, the various pipettes included in a component placement head (e.g., component placement head 100a1) each collect a respective component 106a (e.g., using vacuum to collect and hold a component 106a). After collecting the components 106a, the component placement head (e.g., component placement head 100a1) moves to a position with respect to imaging system 107 such that a component 106a may be imaged with respect to a part of the pipette (or other part of the control module) carrying that component. In a specific example, the component placement head may be moved to a position above an upward looking camera included in imaging system 107. Imaging system 107 is used to collect positional data (e.g., relative positional data between (i) the component 106a held by a pipette, and (ii) the pipette itself or some other part of the control module). Using this positional data, correction may be made (e.g., adjusted about a theta axis) for accurately placing the component 106a on workpiece 110.

FIG. 2A illustrates placement head 100a1 (e.g., placement head 100a1 from FIG. 1). Placement head 100a1 includes includes a plurality of placement assemblies 102a. Each of the placement assemblies 102a includes one of control modules 102a1-102an, and a corresponding pipette 108 (e.g., where pipette 108 is carried by the respective control module, and where the plurality of pipettes are arranged in an array configuration) (in FIG. 2A, the right most pipette 108 is shown extended further downward as compared to the other pipettes 108). Pipette 108 is illustrated carrying a component 106a. For example, each of control modules 102a1-102an may be the same type of control module (e.g., where such control modules may carry the same type of pipette). However, it is understood that different types of control modules may be carried by placement head 100a1. For example, FIG. 2B illustrates another placement head 100a1′ including control modules 102a1′ (where control modules 102a1′ are different from control modules 102a1-102an from FIG. 2A) (in FIG. 2B, only one pipette 108 is shown, but see FIG. 2A for other pipettes). In another example, FIG. 2C illustrates another placement head 100a1″ including a control module 102a1″ (where control module 102a1″ is different from control modules 102a1-102an from FIG. 2A) (in FIG. 2C, only one pipette 108 is shown, but see FIG. 2A for other pipettes). As shown in FIG. 2C, control module 102a1″ is illustrated as a larger module as compared to control module 102a1. As will be appreciated by those skilled in the art, a larger module may be used to place a larger component 106a, to provide a larger placement force, to carry a larger pipette, etc. For example, the geometry of a pipette 108 may differ depending on the size of the component to be picked and placed. Of course, this is just one example of different types of control modules (and corresponding pipettes). A critical aspect of the invention is that, because of the modular nature of the placement assemblies (including control modules and pipettes) of the placement head, different types of placement assemblies may be utilized in a single placement head.

Thus, in accordance with various exemplary aspects of the invention, a placement head includes modules for placing components of different types, and uses a combination of pipettes with different performance specifications for placement of the components of different types.

The various aspects of component placement system 100 shown in FIG. 1 (and detailed embodiments shown in FIGS. 2A-2C) are not limited to a component placement system having that exact configuration. For example, the concept of different types of placement assemblies (e.g., see FIGS. 2B-2C), are applicable to component placement systems 300a-300b shown in FIGS. 3A-3B, or any other component placement system within the scope of the invention.

FIG. 3A illustrates another component placement system 300a. Component placement system 300a includes a plurality of placement heads 100b1-100bn. Each placement head includes a plurality of control modules 102b1-102bn configured for carrying pipettes in a turret configuration. Component placement system 300a also includes a component supply 106 including a plurality of components 106a (e.g., where component supply 106 may include a number of component sources, including components of different types), an imaging system 107 (described above in connection with FIG. 1), and a support structure 104 supporting a workpiece 110 (or a plurality of workpieces 110) configured to receive components 106a. Each placement head (e.g., placement head 100b1) is configured to rotate as shown in FIG. 3A for positioning of the relevant control modules (and associated pipette, not shown for simplicity) for pick and place operations.

FIG. 3B illustrates another component placement system 300b. Component placement system 300b includes a plurality of placement heads 100c1-100cn. Each placement head includes a plurality of control modules 102c1-102cn configured for carrying pipettes in a array configuration (and in FIG. 3B, a matrix array). Component placement system 300b also includes a component supply 106 including a plurality of components 106a (e.g., where component supply 106 may include a number of component sources, including components of different types), an imaging system 107 (described above in connection with FIG. 1), and a support structure 104 supporting a workpiece 110 (or a plurality of workpieces 110) configured to receive components 106a. Each placement head (e.g., placement head 100c1) is configured for motion along a plurality of horizontal axes for positioning of the relevant control modules (and associated pipette, not shown for simplicity) for pick and place operations.

FIG. 4 illustrates elements of a component placement system (such as component placement system 100 in FIG. 1) including a vacuum control system 128, a placement head controller 132, and a plurality of pipettes 108 (where each of the plurality of pipettes are configured to pick and place components). Vacuum control system 128 is included in a placement head (such as placement head 100a1, or other placement heads illustrated and described herein) that includes the plurality of pipettes 108. Placement head controller 132 (also included in the placement head) is configured to selectively control a positive fluid pressure of each of the plurality of pipettes independent of one another (e.g., to selectively release a component from the respective pipette using the positive fluid pressure).

A vacuum source 150 provides vacuum to vacuum control system 128. Vacuum source 150 is configured to continuously provide vacuum to each of the plurality of pipettes for holding the respective component. As shown in FIG. 4, vacuum source 150 is coupled to vacuum gallery 164. More specifically, the vacuum from vacuum source 150 provides vacuum to each of pipettes 108 through vacuum gallery 164. A pressure sensor 162 provides a vacuum pressure at vacuum gallery 164. A pipette flow sensor 156 is provided in the vacuum line between vacuum gallery 164 and each pipette 108. A pipette connection 158 is illustrated upstream of each pipette 108, and each pipette 108 is shown holding a component 106a. While only 2 pipettes 108 are shown in FIG. 4, it is understood that any desired number of pipettes 108 may be included (e.g., the number of pipettes in a placement head may all be coupled to a vacuum gallery 164—such as the 10 pipettes shown in placement head 100a1 in FIG. 2A).

A positive fluid source 152 provides a positive fluid pressure (e.g., pressurized air) to a pressurized air gallery 166 included in vacuum control system 128. The pressurized air (or other fluid/gas) selectively provides a positive fluid pressure for releasing a component 106a from a respective one of pipettes 108. More specifically, the pressurized air from pressurized air gallery 166 is selectively provided to each of pipettes 108 through a respective blow off control structure 168. Thus, placement head controller 132 controls each of the plurality of blow off control structures (independently from one another) to provide the positive fluid pressure to a respective one of the pipettes. A pressure sensor 160 provides an air pressure value from pressurized air gallery 166. Each blow off control structure 168 includes a controllable valve or other structure for opening and closing a line providing the pressurized air from the blow off control structure to the respective pipette 108.

Data from each of the sensors (e.g., pressure sensor 160, pressure sensor 162, pipette flow sensors 156, and pipette pressure sensors 154) is transmitted to placement head controller 132 via communications hub 149. Placement head controller 132 uses the data from the sensors (e.g., either directly, or through a computer, not shown) in connection with operations. For example, placement head controller 132 provides instructions to a blow off control structure 168 (through communications hub 149) for releasing a component 106a from a pipette 108.

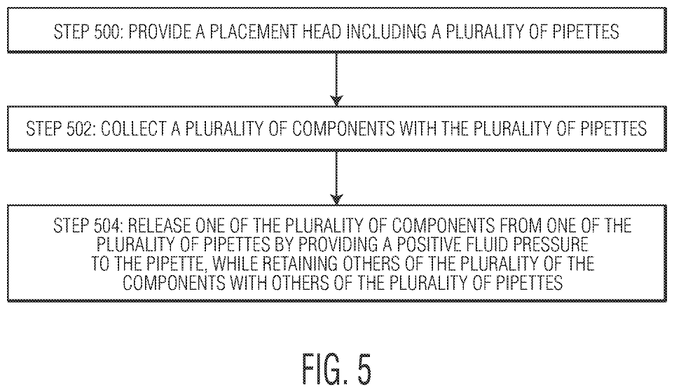

FIG. 5 is a flow diagram illustrating an exemplary method in accordance with the invention. As is understood by those skilled in the art, certain steps included in the flow diagrams may be omitted; certain additional steps may be added; and the order of the steps may be altered from the order illustrated—all within the scope of the invention.

FIG. 5 is a flow diagram illustrating a method of operating a component placement system. At Step 500, a placement head including a plurality of pipettes is provided (e.g., see placement heads 100a1 in FIGS. 1 and 2A and 3, placement head 100a1′ in FIG. 2B, placement head 100a1″ in FIG. 2C, placement head 100b1 in FIG. 3A, and placement head 100c1 in FIG. 3B). At Step 502, a plurality of components are collected with the plurality of pipettes (e.g., collected from one or more component sources, such as component supply 106) (e.g., collected by providing vacuum to each of the plurality of pipettes for collecting the plurality of components). The plurality of components may be collected as desired (e.g., one component being collected at a time, or any other method). After being collected, the plurality of components are held by the placement head, where each component is held by a respective pipette. At Step 504, one of the plurality of components is released from one of the plurality of pipettes by providing a positive fluid pressure to the pipette, while retaining others of the plurality of the pipettes with others of the plurality of pipettes. This Step 504 effectively places the one of the components on a workpiece by the step of releasing. The plurality of components may be placed as desired by selectively providing the positive fluid pressure the respective pipette(s) (e.g., one component being placed at a time, or any other method). For example, one component may be placed (released) by a first pipette while other components are held by other pipettes. While being held by the other pipettes (during placement of the first component), adjustment may be made (e.g., position adjustments, force adjustments, etc.) in preparation for placement (release) of the other components.

Through the present invention, a number of benefits are achieved. By releasing the components using a positive pressure (that overcomes the continuous vacuum), a reduced number of components may be utilized in the component placement system. For example, individual valves (and related components) are not needed to release vacuum from one (or more than one) pipette. The vacuum may be maintained on all pipettes while releasing the desired component through the use of positive pressure at the respective pipette.

Although the invention is illustrated and described herein with reference to specific embodiments, the invention is not intended to be limited to the details shown. Rather, various modifications may be made in the details within the scope and range of equivalents of the claims and without departing from the invention.

1. A component placement system comprising:
a placement head including a plurality of pipettes, each of the plurality of pipettes being configured to pick and place components;
a vacuum source for providing vacuum to each of the plurality of pipettes for holding a component; and
a positive fluid source for selectively providing a positive fluid pressure for releasing the component from a respective one of the plurality of pipettes.

2. The component placement system of claim 1 wherein the component placement system includes a plurality of the placement heads, and each of the plurality of placement heads including at least 3 of the plurality of pipettes.

3. The component placement system of claim 1 wherein the plurality of pipettes are arranged in the placement head in at least one of (i) an array configuration and (ii) a turret configuration.

4. The component placement system of claim 1 wherein the positive fluid source is configured to provide an air pulse to release the component from a respective one of the plurality of pipettes.

5. The component placement system of claim 1 wherein the positive fluid source is configured to provide an air pulse that overcomes vacuum provided by the vacuum source at one of the plurality of pipettes to release the component from the one of the plurality of pipettes.

6. The component placement system of claim 1 further comprising a sensor for detecting whether the component is held by the respective one of the plurality of pipettes.

7. The component placement system of claim 1 wherein the sensor includes a pressure sensor and a flow sensor.

8. The component placement system of claim 1 further comprising a placement head controller for selectively controlling the positive fluid pressure for releasing the component from the respective one of the plurality of pipettes.

9. The component placement system of claim 1 further comprising a placement head controller for selectively controlling the positive fluid pressure at each of the plurality of pipettes of the placement head.

10. The component placement system of claim 9 wherein the placement head controller is configured to selectively control the positive fluid pressure of each of the plurality of pipettes independent of one another.

11. The component placement system of claim 1 further comprising a plurality of blow off control structures controlled by the placement head controller, wherein each of the plurality of blow off control structures is configured to provide the positive fluid pressure to a respective one of the pipettes.

12. The component placement system of claim 1 wherein the vacuum source continuously provides vacuum to each of the plurality of pipettes through a vacuum gallery.

13. A method of operating a component placement system, the method comprising the steps of:
(a) providing a placement head including a plurality of pipettes;
(b) collecting a plurality of components with the plurality of pipettes; and
(c) releasing one of the plurality of components from one of the plurality of pipettes by providing a positive fluid pressure to the pipette, while retaining others of the plurality of the components with others of the plurality of pipettes.

14. The method of claim 13 wherein step (b) includes providing vacuum to each of the plurality of pipettes for collecting the plurality of components.

15. The method of claim 13 wherein step (c) includes placing the one of the components on a workpiece by the step of releasing.

16. The method of claim 13 step (c) includes releasing the one of the plurality of components by providing an air pulse from a positive fluid source to overcome vacuum provided by a vacuum source at the one of the plurality of pipettes.

17. The method of claim 13 wherein during step (c), the others of the plurality of the components are retained by the others of the plurality of pipettes, using vacuum provided by a vacuum source to the others of the plurality of pipettes.
